(19) United States
(12) Patent Application Publication
(10) Pub. No.: US 2021/0079513 A1
(43) Pub. Date: Mar. 18, 2021

(54) In Situ Density Control During Fabrication Of Thin Film Materials

(71) Applicant: Halliburton Energy Services, Inc., Houston, TX (US)

(72) Inventors: James M. Price, Cypress, TX (US); Jian Li, Bellaire, TX (US)

(73) Assignee: Halliburton Energy Services, Inc., Houston, TX (US)

(21) Appl. No.: 16/621,524

(22) PCT Filed: Jun. 25, 2018
(86) PCT No.: PCT/US2018/039349

§ 371 Date: Dec. 11, 2019

(51) Int. Cl. C23C 14/30; C23C 14/10; C23C 14/14

(52) U.S. Cl. CPC C23C 14/30; C23C 14/545; C23C 14/14; C23C 14/10

(57) ABSTRACT

A system and method for forming a thin film device. A method may comprise depositing a layer of material on a substrate with a thin film system at a deposition rate, monitoring a density of the layer of material to control the deposition rate, selecting a threshold for the deposition rate for a consistent film density, wherein the threshold is a material density, decreasing the deposition rate when the deposition rate is higher than the threshold, and increasing the deposition rate when the deposition rate is lower than the threshold. A thin film system for fabricating a thin film device may comprise a chamber, a material source contained with the chamber, an electrical component to activate the material source, a substrate holder to support a multilayer stack of materials that form the thin film device, a measurement device, and an information handling system.

### BACKGROUND

Manufacturing of thin-film is used in the optical filter industry, optical coating industry, semiconductor industry, solar cell industry, defense industry, commercial aerospace, medical, telecom, and the like. The fabrication of thin-films has allowed for the creation of narrow band and broad band optical filters, automotive electronics, consumer electronics, transistors, source channels, gate dielectrics, metal electrodes, and other small device. Such devices may be created through an act of applying a thin film to a surface, also known as deposition. During the manufacturing process of thin-film materials, controlling the deposition rate and film density during fabrication may be essential to producing a reliable working device.

Disclosed below are systems and methods for a thin film based measurement approach to control both the deposition rate and film density during the fabrication of thin film materials such as an integrated computational element (“ICE”), narrow band filters, broad band filters, semiconductor gate stack materials, and optical coatings. Current methods identify ways to control the fabrication process by monitoring only the rate of deposition. However, these different methods may result in an inhomogeneous density profile, which may adversely affect the optical throughput and ability to achieve the targeted design accuracy.

### BRIEF DESCRIPTION OF THE DRAWINGS

These drawings illustrate certain aspects of some examples of the present disclosure, and should not be used to limit or define the disclosure.

FIG. 1 illustrates an example of a thin film system;

FIG. 2 illustrates an example of an integrated computational element; and

FIG. 3 illustrates a graph of a depth profile.

### DETAILED DESCRIPTION

The present disclosure may generally relate to optical thin-films and, more particularly, to systems and methods of using optical methods for measuring and controlling deposition processes in the fabrication of optical thin-films. Specifically, this disclosure illustrates different examples based on x-ray reflectivity to monitor the density of the deposited material in real time and control the deposition process. Systems and methods may include a chamber, a material source contained within the chamber, an electrical component to activate the material source, a substrate holder to prevent the substrate from moving during the deposition process and at least one witness sample. The system may further include a measurement device and an information handling system. The material source provides a layer of material to the multilayer stack, and to the witness sample at a deposition rate controlled at least partially by the electrical component and based on a correction value obtained by the information handling system. In some examples, the correction value is based on a measured value provided by the information handling system.

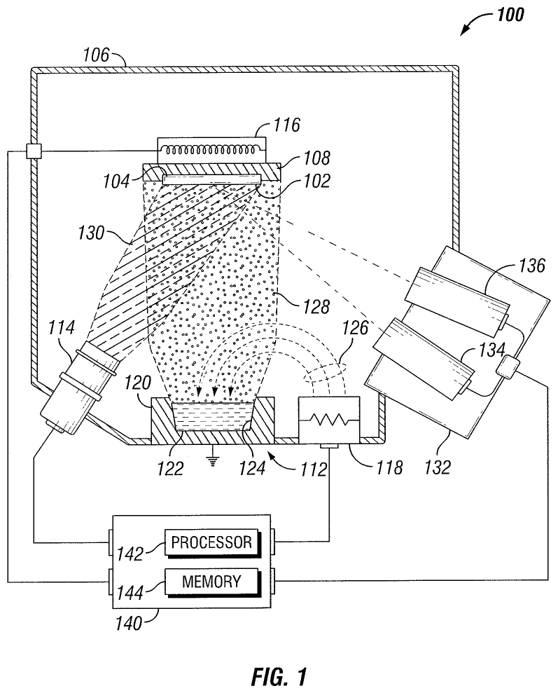

FIG. 1 illustrates a thin-film system 100 that may be used for fabricating a thin-film device, according to one or more examples. It should be noted, that for the purpose of this disclosure a thin film device may comprise an integrated computational element (“ICE”), narrow band filters, broad band filters, semiconductor gate stack materials, and optical coatings. For the sake of brevity, all thin film devices are referred to as an ICE for this disclosure. Accordingly, thin-film system 100 may be configured to fabricate an integrated computational element (“ICE”) 102 on a substrate 104. Substrate 104 may be similar to and made of one or more materials (discussed below) for an optical substrate (discussed below). In examples, ICE 102 may be configured to transmit an optical spectrum representing a chemical constituent of a production fluid from a wellbore and/or other fluid. Additionally, ICE 102 may be configured to reflect an optical spectrum representing a chemical constituent of a production fluid from a wellbore and/or other fluid. It should be noted that ICE 102 may also be considered an optical element, which may act as an optical interference based device that may be designed to operate over a continuum of wavelengths in the electromagnetic spectrum from the UV to mid-infrared (MIR) ranges, or any subset of that region. ICE 102 modifies and processes the electromagnetic radiation that optically interacts with the substance. A detector reads the modified interacted electromagnetic radiation, thus correlating an output of the detector to the physical or chemical property of the substance under analysis.

An exemplary optical thin-film based ICE 102 may include a plurality of optical layers consisting of various materials whose index of refraction and size (e.g., thickness) may vary between each layer. The design of an ICE 102 (which may be referred to as an “ICE design”) refers to the number and thicknesses of the respective layers of ICE 102. The layers may be strategically deposited and sized so as to selectively pass predetermined fractions of electromagnetic radiation at different wavelengths configured to substantially mimic a regression vector corresponding to a particular physical or chemical property of interest of a substance. Accordingly, a design of ICE may exhibit a transmission function that is weighted with respect to wavelength. As a result, the output light from ICE 102 conveyed to the detector may be related to the physical or chemical property of interest for the substance. It should be noted that the various disclosed systems and methods may be equally applicable to fabrication of any thin-film used in thin-film applications. Such application areas and technology fields may include, but are not limited to, the oil and gas industry, food and drug industry, industrial applications, the mining industry, the optics industry, the eyewear industry, the electronics industry, and the semiconductor fabrication industry.

Thin-film system 100 includes a chamber 106, or vessel, and a substrate holder 108. In examples, chamber 106 may be placed and maintained at a low pressure to facilitate material deposition. For example, chamber 106 may be set to about 10−7 Torr. Substrate holder 108 may secure substrate 104 within chamber 106 relative to a mass-flux generator 112 and an ion-beam generator 114. It should be noted that substrate 104 may comprise a multilayer stack of materials. Substrate holder 108 may include a heater 116 for raising and maintaining a temperature of substrate 104 above ambient. For example, heater 116 may be mechanically decoupled from substrate 104. Additionally, heating lamps, (e.g., halogen lamps) inside chamber 106 may be used to uniformly heat the entire chamber 106 and substrate 104 to a desired temperature.

Mass-flux generator 112 may be coupled to chamber 106 and may include an electron gun 118 and a crucible 120 for heating a mass source 122. Mass source 122 may be contained within a pocket 124 of crucible 120 and may be disposed adjacent electron gun 118. Electron gun 118 may be configured to generate a beam of electrons (e.g., e-beam 126) from a filament and arc the e-beam 126 into pocket 124 of crucible 120 via an electromagnetic field. The electromagnetic field used to direct e-beam 126 onto mass source 122 may be generated with a magnetron, according to some examples. Energy from e-beam 126 may be absorbed by mass source 122, inducing evaporation of the mass source. A water cooling circuit (not shown) may also be incorporated into crucible 120 to prevent crucible 120 from decomposing or melting. Crucible 120 may be electrically grounded, and evaporation of mass source 122 may be operable to generate a mass flux 128 that may be received by substrate holder 108.

Mass flux 128 may include elements, molecules, or a combination thereof. Impingement of mass flux 128 onto substrate 104, or onto existing films already formed on the substrate 104, forms a film in ICE 102. In examples, crucible 120 may include two or more pockets 124 for holding two or more different mass sources 122. Additionally, electron gun 218 arcs the beam of electrons 126 into the appropriate pocket 124 to heat the desired mass source 122. This configuration may allow thin-film system 100 to fabricate ICE 102 with minimal exposure of chamber 106 to an ambient environment (i.e., to introduce a new or different mass source 122). In at least one example, crucible 120 contains two or more pockets 124 for containing mass sources of Si and Si02. In these examples, mass-flux generator 112 may be operational to form films of, respectively, Si and Si0₂ (e.g., ICE 102). It should be noted that other techniques may be utilized. For example, two separate electron guns for Si and Si0₂, respectively, might equally be used, without departing from the scope of the disclosure.

Ion-beam generator 114 may be configured to produce and direct an ion beam 130 of elements, molecules, or a combination thereof towards substrate 104. Ion beam 130 impinges upon the forming film and may promote control over film properties such as morphology, density, stress level, crystallinity, and chemical composition. In examples, ion-beam generator 114 may produce ion beam 130 using a mixed gas source. The mixed gas source may be pre-mixed before introduction into chamber 106 or may be mixed in chamber 106, proximate to ion-beam generator 114. Non-limiting examples of mixed gas sources include argon gas and silane gas, argon gas and methane gas, argon gas, methane gas, and tetrafluoromethane gas, and/or any combinations thereof. The aforementioned mixed gas sources may be operable to form films of, respectively, hydrogenated amorphous silicon films, films of silicon carbide, and films of silicon carbide alloy, Si1-x-y-zCxHyFz. The compositional boundaries of the silicon carbide alloy may be defined by the relation: x+y+z<1 where x is non-zero.

Accordingly, in some examples thin-film system 100 may encompass an Ion Assisted E-beam (“E-beam”) deposition tool in which the rate of evaporation in crucible 120 is proportional to the voltage applied to the E-beam by electron gun 118. It should be noted that E-beam may be replaced by an ion-source. In embodiments, an ion-source may act, function, and/or operate similar to the E-beam. A higher voltage increases the evaporation and deposition rate onto ICE 102, resulting in a less dense layer. In examples, lowering the voltage in electron gun 118 may decrease deposition rate and produces a denser layer. More generally, deposition rate during E-beam evaporation and other physical vapor deposition methods may be affected by factors other than a voltage in electron gun 118. A change in deposition rate may result from numerous dynamic process variables such as pressure, pumping speed, and temperature in chamber 106. Other factors that may affect the deposition rate include, but are not limited to, the source material surface and preparation, cooling of electron gun 118 and of crucible 120, and flux of ion beam generator 114.

It should be noted that some of the above mentioned dynamic process variables fluctuate during the fabrication process. In many instances, these fluctuations become difficult to monitor and control as would be desirable. Some examples overcome the variability in thin-film deposition rate by monitoring a density of the layer of material to control the deposition rate (in real time) and providing the data to a proportional-integral-derivative (PID) loop which then adjusts the voltage of electron gun 118.

In some examples, as illustrated, a measurement device 132 may be coupled to or otherwise associated with chamber 106. Measurement device 132 may be oriented towards substrate 104 and configured to measure in-situ a thickness, a complex index of refraction, or both, of a film being formed by mass-flux generator 112. Accordingly, measurement device 132 may be configured to perform optical, mechanical, and even electrical measurements on ICE 102. In some examples, measurement device 132 may include an ellipsometer 134 for measuring the thickness, the complex index of refraction, or both. In some examples, measurement device 132 may include a spectrometer 136 for measuring an optical spectrum of ICE 102 during fabrication. In some examples, measurement device 132 includes a quartz monitor or a single wavelength monitor for thickness. The quartz monitor includes the use of a quartz crystal microbalance as the deposition rate monitor. During deposition, the quartz crystal monitor measures the deposition rate and feeds the results into a proportional-integral-derivative (PID) loop to correct voltage in electron gun 118. Some examples may include a plurality of quartz crystal microbalances arranged in different points within chamber 106. Thus, averaging the measurements of the multiple crystal monitors placed inside chamber 106 may provide accurate deposition rate values.

Measurement device 132 may include an optical monitor such as an ellipsometer 134, a spectrometer 136, and/or interferometer. More specifically, measurement device 132 may include a broadband light source and a CCD array detector. In some configurations, measurement device 132 collects optical data from a witness sample in real time. The optical data is incorporated into an optical model to determine film thickness (as a function of time). The calculated deposition rate is then forwarded to the PID loop to correct the voltage of electron gun 118. More specifically, the optical data may include a transmission spectrum, a reflection spectrum, an interference spectrum, or a combination thereof. The optical model then matches the measured optical data (e.g., spectra) with a selected layer thickness. Accordingly, in some examples the selected layer thickness is determined from the optical model that best fits the data.

Optical measurements may also prove useful in obtaining further information from the thin-film deposition process in addition to the thickness of the layer. For instance, optical measurements may provide the real and imaginary components of the complex index of refraction, n and k, of a layer, in real time. In that regard, when the optical properties of the layers change during fabrication, this information may be relayed back to electron gun 118, to correct for it. For example, second, third, fourth and further Si layers desirably have similar indices of refraction, regardless of their different thicknesses. However, a lower index of refraction may indicate a more porous film, fabricated at a higher deposition rate. If during the course of Si deposition, the measured index of refraction may be lower than a predetermined standard value, this information may be relayed to the PID loop in order to alter operation of electron gun 218 and thereby decrease electron beam voltage to reduce deposition rate and yield a more dense Si material.

In examples consistent with the present disclosure, the PID loop may prove useful in helping to continuously adjust and otherwise maintain a voltage in electron gun 118 and other parameters, such as pressure and temperature inside chamber 106, thereby inducing a desired deposition rate. Further, according to some examples, the PID loop may also be configured to help control the electromagnetic field used to generate e-beam 126. Deposition rates in thin-film system 100 may vary from about 1 to about 5 Angstrom per second (A/sec). In examples consistent with the present disclosure, the deposition rate may be controlled to within a fraction of an A/sec.

For example, in some examples consistent with the present disclosure, a deposition rate of about 3 A/sec may be controlled by a PID loop to within approximately 0.25 A/sec or even less. In that regard, optical measurements obtained as disclosed herein may provide a more accurate and less noisy value for the deposition rate relative to the quartz crystal microbalance measurements. Accordingly, optical measurements obtained as disclosed herein include thin-film models that use optical parameters across a broad spectral band, therefore providing a more robust measurement for the layer thickness. As may be appreciated, a more robust optical measurement may be less prone to drift or adversely affected by system fluctuations.

While not explicitly shown, in some examples, measurement device 132 may include a probe and a detector disposed on opposing sides of chamber 106 and at the same angle of incidence. While probes, (e.g., ellipsometer 134 and spectrometer 136) may be coupled on one side of chamber 106, it should be understood that corresponding detectors may be coupled on an opposite side of chamber 106. Accordingly, FIG. 1 depicts measurement device 132, in ‘reflection mode.’ In other examples, however, measurement device 132 may be configured in transmission mode. Substrate 104 in FIG. 1 may act as a ‘witness sample,’ according to some examples. A witness sample, for example, may be a substrate that may include ICE 102 or a test film, on which measurement device 132 performs optical measurements.

An information handling system 140 may be communicably coupled to mass-flux generator 112 and to ion-beam generator. Information handling system 140 may include one or more processors 142 and one or more memories 144 to control film formation during fabrication of ICE 102. Information handling system 140 may be further coupled to heater 116, if present, to manipulate the temperature of substrate 104 during fabrication. Information handling system 140 may couple measurement device 132 to control the thickness, the complex index of refraction, or both, of a layer formed by mass-flux generator 112. Thus, in some examples, information handling system 140 may execute the PID loop. It should be noted that information handling system 140 may include optical computing devices, which may be referred to as “optico analytical devices,” which may be used to analyze and monitor a substance in real time. Such optical computing devices may often employ a light source emitting electromagnetic radiation that reflects or refracts from a substance and optically interacts with an optical processing element to determine quantitative and/or qualitative values of one or more physical or chemical properties of the substance.

During operations of thin-film system 100, a vacuum is formed in chamber 106 and an e-beam 126 emanates from the electron gun 118. E-beam 126 is directed into pocket 124 of crucible 120 by the electromagnetic field. Evaporation of mass source 122 produces mass flux 128, which traverses a distance from the crucible 120 to substrate holder 108. Mass flux generator 112 directs mass flux 128 toward substrate 104 to form a layer in ICE 102. The layers in ICE 102 may include a dielectric layer (such as Si0₂), or a semiconducting layer (such as Si), or even a conducting layer (such as Aluminum—Al—).

In coordination with mass-flux generator 112, ion-beam generator 114 directs ion beam 130 towards substrate 104. Such coordination may be managed by information handling system 140 to control film formation during fabrication of ICE 102. When a layer has achieved its desired thickness, information handling system 140 deactivates mass-flux generator 112 and ion beam generator 114. Heater 116, if present, may be functional during the formation process in order to improve film properties. Information handling system 140 regulates mass-flux generator 112 and ion beam generator 114 to form a series of sequential films. The number, thickness, and refractive index (i.e., material) of sequential films in the series may be specified by a target transmission or reflection spectrum of ICE 102. The design of ICE 102 may produce alternating layers (discussed below) of high index of refraction and layers (discussed below) of low index of refraction. A terminal or capping layer (discussed below) may also be formed.

During fabrication of ICE 102, information handling system 140 may also controls measurement device 132. Measurement device 132 may be operational to measure in-situ a thickness, a complex index of refraction, or both, of a layer formed in ICE 102. Measurement device 132 may be configured to perform an optical measurement on ICE 102, for example, for at least one wavelength. In some examples, measurement device 132 may include a broadband system to measure reflection/transmission spectra at multiple wavelengths. For example, in some examples a broadband reflection/transmission measurement may span a continuous multi-wavelength wavelength range from about 1.4 μm to about 2.5 μm, or more.

The optical measurement on ICE 102 may be in transmission mode, in reflection mode, or in transmission and reflection modes. In some examples, information handling system 140 stores the optical measurement in a database, as each of the layers is deposited on ICE 102. In some examples, information handling system 140 may also incorporate the optical measurement into the PID loop to adjust the deposition rate in real time, if desired. One or more processors 142 and one or more memories 144 of information handling system 140 are operable to develop or receive an optical model of ICE 102 as is being fabricated, using data stored in the database. Processors 142 and memories 144 may use the optical model to obtain a thickness of the layer deposited on ICE 102, in combination with data provided by measurement device 132.

Consistent with the present disclosure, ICE 102 may be fabricated using systems that employ other deposition techniques. Deposition techniques used to form the layers in ICE 102 may include, but are not limited to, unassisted electron beam evaporation, thermal evaporation, dc-sputtering, dc-magnetron sputtering, rf-sputtering, reactive physical vapor deposition (RPVD), physical vapor deposition (PVD), pulsed laser deposition (PLD), low pressure chemical vapor deposition (LPCVD), plasma-enhanced chemical vapor deposition (PECVD), atmospheric pressure chemical vapor deposition (APCVD), metal organic chemical deposition (MOCVD), and molecular beam epitaxy (MBE). Other deposition techniques are possible, by any feasible combination of the above techniques, as one of ordinary skill will recognize.

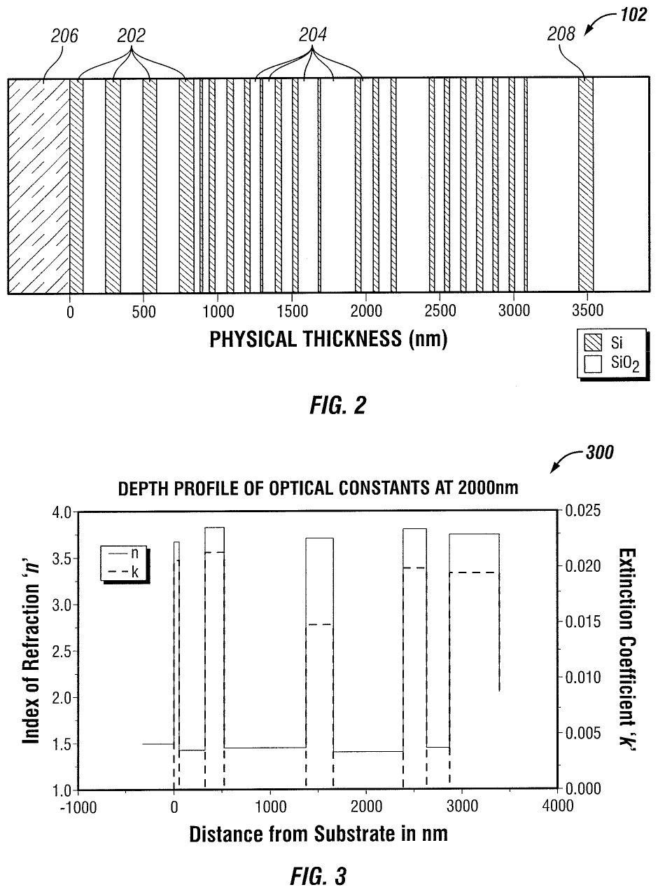

Referring to FIG. 2, illustrates an ICE 102, according to one or more examples of the present disclosure. As illustrated, ICE 102 may include a plurality of alternating layers 202 and 204, such as silicon (Si) and Si02 (quartz), respectively. In general, these layers 202, 204 may include material with an index of refraction that may be high and low, respectively. Generally, the index of refraction is a complex number having an imaginary part associated with absorption effects. Other examples of materials might include niobia and niobium, germanium and germania, MgF₂, Si0₂, and other high and low index materials known in the art. Layers 202, 204 may be strategically deposited on an optical substrate 206. In examples, optical substrate 206 may be BK-7 optical glass. In other examples, optical substrate 206 may be another type of optical substrate, such as quartz, sapphire, silicon, germanium, zinc selenide, zinc sulfide, or various plastics such as polycarbonate, polymethylmethacrylate (PMMA), polyvinylchloride (PVC), diamond, ceramics, combinations thereof, and the like. At the opposite end (e.g., opposite optical substrate 206 in FIG. 2), ICE 102 may include a layer 208 that is generally exposed to the environment of the device or installation, and may be able to detect a sample substance. The number of layers 202, 204 and the thickness of each layer 202, 204 may be determined from the spectral attributes acquired from a spectroscopic analysis of a characteristic of the substance being analyzed using a conventional spectroscopic instrument. The spectrum of interest of a given characteristic typically includes any number of different wavelengths.

It should be understood that ICE 102 in FIG. 2 may not in fact represent any particular ICE 102 configured to detect a specific characteristic of a given substance, but is provided for purposes of illustration only. Consequently, the number of layers 202, 204 and their relative thicknesses, as shown in FIG. 2, bear no correlation to any particular substance or characteristic thereof. Nor are layers 202, 204 and their relative thicknesses necessarily drawn to scale, and therefore should not be considered limiting of the present disclosure.

In some examples, material of each layer 202, 204 may be doped or two or more materials may be combined in a manner to achieve the desired optical characteristic. In addition to solids, ICE 102 may also contain liquids and/or gases, optionally in combination with solids, in order to produce a desired optical characteristic. In the case of gases and liquids, ICE 102 may contain a corresponding vessel (not shown), which houses the gases or liquids. In examples, variations of ICE 102 may also include holographic optical elements, gratings, piezoelectric, light pipe, and/or acousto-optic elements, for example, that may create transmission, reflection, and/or absorptive properties of interest.

Multiple layers 202, 204 may exhibit different refractive indices. By properly selecting the materials of layers 202, 204 and their relative thickness and spacing, ICE 102 may be configured to selectively pass/reflect/refract predetermined fractions of electromagnetic radiation at different wavelengths. Each wavelength is given a predetermined weighting or loading factor. The thickness and spacing of the layers 202, 204 may be determined using a variety of approximation methods from the spectrum of the characteristic or analyte of interest. These methods may include inverse Fourier transform (IFT) of the optical transmission spectrum and structuring ICE 102 as the physical representation of the IFT. The approximations convert the IFT into a structure based on known materials with constant refractive indices.

The weightings that layers 202, 204 of ICE 102 apply at each wavelength may be set to the regression weightings described with respect to a known equation, data, or spectral signature. For instance, when electromagnetic radiation interacts with a substance, unique physical and chemical information about the substance may be encoded in the electromagnetic radiation that may be reflected from, transmitted through, or radiated from the substance. This information is often referred to as the spectral “fingerprint” of the substance. ICE 102 may be configured to perform the dot product of the received electromagnetic radiation and the wavelength dependent transmission function of ICE 102. The wavelength dependent transmission function of ICE 102 may be dependent on the material refractive index of each layer, the number of layers 202, 204 and thickness of each layer 202, 204. Thus, it may be appreciated that performing spectroscopic measurements on layers 202, 204 during fabrication may indicate proper or improper refractive indices and layer 202, 204 thicknesses, and further enable correction adjustments as necessary for proper operation of ICE 102 upon fabrication completion.

Examples of correction adjustments as disclosed below may provide a thin-film based optical measurement approach to control the deposition rate of a layer. The thin-film based optical measurement may be applied during fabrication of an optical thin-film. The thin-film stack, for example, may be an ICE 102 as described herein. The precise stoichiometry of a deposited layer has an impact on the optical properties of thin-films. The stoichiometry may be controlled during the fabrication process by establishing and otherwise regulating the deposition rate of the layer. A reliable, constant, or approximately constant deposition rate (during thin-film deposition) may enable both the high index of refraction (the real part) (e.g., Si) and low index of refraction (the real part) (e.g., SiO₂) layers to maintain a consistent specification during the course of ICE 102 fabrication process. Moreover, a more precise control of the deposition rate enhances the accuracy of end-point detection for layer termination, thus enabling precise layer thickness results in the fabrication process. Thus, examples consistent with the present disclosure may avoid overshoot errors resulting in layers having a thickness greater than desired. It may be appreciated by those skilled in the art that examples in this disclosure may be used in combination with alternative deposition rate detection methods such as X-ray reflectivity.

Thin-film system 100 (Referring to FIG. 1), as discussed above uses electromagnetically focused high energy e-beam 126 onto a target (either Si or Si0₂) to evaporate an atomic species. The ion assisted beams may then help focus and density the vapor atomic species onto optical substrate 206 (Referring to FIG. 2), such as a glass substrate. The rate of evaporation may be directly proportional to the voltage applied to the E-beam. However, a drawback of physical vapor deposition methods, such as E-beam evaporation, is that the deposition rate is not exclusively controlled by the voltage of E-beam 126 (Referring to FIG. 1). A change in deposition rate may be attributed to the numerous dynamic process variables (chamber pressure, pumping speed, temperature, source material surface and preparation, E-beam and source material crucible cooling, and ion gun flux) that fluctuate during the course of the deposition. It may be difficult to monitor and control each of these variables at the same time. A simpler solution to correct for the variable thin film evaporation process may be to monitor the deposition rate (in real time) and provide that data to a proportional-integral-derivative (PID) loop. A proportional-integral-derivative controller (PID controller) is a control loop feedback mechanism requiring continuously modulated control. A PID controller continuously calculates an error value as the difference between a desired setpoint (SP) and a measured process variable (PV) and applies a correction based on proportional, integral, and derivative terms. For example, the PID loop automatically applies accurate and responsive correction to a control function, which then corrects the voltage of E-beam 126 in order to target a constant deposition rate (3 A/sec). The control function may comprise a threshold set by an operator. An operator may be defined as an individual, group of individuals, or an organization. For example, if the density of the layer of material that is being measured has a higher deposition rate or a lower deposition rate of a desired threshold, the PID loop may automatically alter the voltage and/or current of an E-beam 126 and/or an ion-source. It should be noted that the threshold may measure consistent film density, material density, a desired stoichiometry, and/or optical thickness. This approach may be performed with the use of a quartz crystal microbalance as the deposition rate monitor. During deposition, the crystal monitor measures the deposition rate and feeds the results into a PID loop to correct the current of E-beam 126. Alternatively, a single-wavelength optical monitor system may be also be used to monitor and control the deposition rate.

However, even for a targeted fixed-rate deposition process, the resulting deposited film may have an inhomogeneous density profile. This, in turn, may produce different optical properties that may not be repeatable or predictable and may cause the fabrication to not be able to produce a targeted design. As an example, FIG. 3 illustrates depth profile 300 of the optical properties (index of refraction ‘n’ and extinction coefficient ‘k’) at 1000 nm wavelength for a 9-layer fabricated ICE 102 (Referring to FIG. 1) thin film stack. As illustrated in FIG. 3, the relative change of ‘n’ for the Si layers is up to 4.4%. For an ICE 102 with a total Si thickness of 2500 nm which may be inside the typical thickness range, a relative change of 4.4% in “n” is approximately equivalent to an absolute thickness change of 110 nm if “n” were constant. In most cases, missing the total Si thickness by 110 nm will make the final ICE 102 product fail. A similar effect may be observed for the extinction coefficient ‘k’ and for the ‘n’ of Si0₂ layers. To a large extent, these variations may be explained by the materials densities that are known to depend on the deposition conditions such as rate, temperature, voltage bias, substrate temperature. Therefore, the variations of materials density may be fed into the PID loop in order to achieve the best performance for thin-film system 100 performance to produce ICE 102.

As illustrated by FIG. 3, a deposition process may be useful where the film density may be held at a constant. An X-ray reflectivity (“XRR”) based method may monitor the thickness and density of ICE 102 during fabrication in such a way as to replace the quartz crystal microbalance method described above. An X-ray reflectivity thin-film measurement method may determine the density of a deposited material without relying on any user-defined model. For example, an XRR measurement may include measuring reflected X-ray intensity as a continuous function of an incident angle. An angle at which the X-rays undergo a transition from total external reflection to penetration into the material is defined as the critical angle. The critical angle for most thin film materials is typically between 0.1˜0.5 degrees. In general, a thin film with a larger electron density may have a larger critical angle compared to a film with a smaller electron density. The density of the film may then be calculated from the critical angle. Determining the density of the material may be established by monitoring the XRR intensity as a function of angle and identifying the critical angle at which the XRR intensity changes from total reflection. For example, monitoring XRR may include taking the measurement of a witness sample during fabrication followed by feeding the determined density to a measurement control system (i.e. PID loop). In addition, the film thickness may be extracted by the interference fringes.

XRR may be able to identify the deposited film thickness density in-situ and in real time, and then feed that data to a PID loop to control E-beam 126 (Referring to FIG. 1) and ion-source characteristics in order to provide a constant density. The XRR method may be an X-ray based approach as opposed to an optical or electro-mechanical based approach and may control a constant film density as opposed to a constant deposition rate.

This method and system may include any of the various features of the compositions, methods, and system disclosed herein, including one or more of the following statements.

Statement 1: A method of forming a thin film device may comprise depositing a layer of material on a substrate with a thin film system at a deposition rate; monitoring a density of the layer of material to control the deposition rate; selecting a threshold for the deposition rate for a consistent film density, wherein the threshold is a material density; decreasing the deposition rate when the deposition rate is higher than the threshold; and increasing the deposition rate when the deposition rate is lower than the threshold.

Statement 2: The method of statement 1, wherein monitoring the density is performed in-situ.

Statement 3: The method of statement 1 or statement 2, wherein monitoring the density is performed by X-ray reflectivity.

Statement 4: The method of any previous statement, wherein the threshold is a stoichiometry of the layer of material.

Statement 5: The method of any previous statement, wherein the threshold is an optical thickness of the layer of material.

Statement 6: The method of any previous statement, wherein the threshold is an optical property of the material.

Statement 7: The method of any previous statement, further comprising adjusting the thin film system by changing an E-beam current.

Statement 8: The method of any previous statement, further comprising adjusting the thin film system by changing an ion-source current.

Statement 9: The method of any previous statement, further comprising adjusting the thin film system by changing an ion-source voltage.

Statement 10: The method of any previous statement, wherein monitoring a density of the layer of material is performed by an ellipsometer, a spectrometer, or an interferometer.

Statement 11: A thin film system for fabricating a thin film device may comprise a chamber; a material source contained with the chamber; an electrical component to activate the material source; a substrate holder to support a multilayer stack of materials that form the thin film device; a measurement device; and an information handling system configured to control the measurement device to monitor a density of a layer of material deposited on a substrate to control a deposition rate, select a threshold for the deposition rate for a consistent film density; decrease the deposition rate when the deposition rate is higher than the threshold with the electrical component or increase the deposition rate when the deposition rate is lower than the threshold with the electrical component.

Statement 12: The thin film system of statement 11, wherein the measurement device comprises an ellipsometer, a spectrometer, or an interferometer.

Statement 13: The thin film system of statement 11 or statement 12, wherein the information handling system operates in-situ to decrease the deposition rate or increase the deposition rate.

Statement 14: The thin film system of statement 11-statement 13, wherein the measurement device measures the density of the layer of material by X-ray reflectivity.

Statement 15: The thin film system of statement 11-statement 14, wherein the threshold is an optical thickness of the layer of material.

Statement 16: The thin film system of statement 11-statement 15, wherein the threshold is an optical property of the material.

Statement 17: The thin film system of statement 11-statement 16, wherein the information handling system is further configured to adjust the thin film system by changing an E-beam current.

Statement 18: The thin film system of statement 11-statement 17, wherein the information handling system is further configured to adjust the thin film system by changing an ion-source current.

Statement 19: The thin film system of statement 11-statement 18, wherein the information handling system is further configured to adjust the thin film system by changing an ion-source voltage.

Statement 20: The thin film system of statement 11-statement 19, wherein the threshold is a stoichiometry of the layer of material.

The preceding description provides various examples of the systems and methods of use disclosed herein which may contain different method steps and alternative combinations of components. It should be understood that, although individual examples may be discussed herein, the present disclosure covers all combinations of the disclosed examples, including, without limitation, the different component combinations, method step combinations, and properties of the system. It should be understood that the compositions and methods are described in terms of “comprising,” “containing,” or “including” various components or steps, the compositions and methods may also “consist essentially of” or “consist of” the various components and steps. Moreover, the indefinite articles “a” or “an,” as used in the claims, are defined herein to mean one or more than one of the element that it introduces.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any included range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited.

Therefore, the present examples are well adapted to attain the ends and advantages mentioned as well as those that are inherent therein. The particular examples disclosed above are illustrative only, and may be modified and practiced in different but equivalent manners apparent to those skilled in the art having the benefit of the teachings herein. Although individual examples are discussed, the disclosure covers all combinations of all of the examples. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative examples disclosed above may be altered or modified and all such variations are considered within the scope and spirit of those examples. If there is any conflict in the usages of a word or term in this specification and one or more patent(s) or other documents that may be incorporated herein by reference, the definitions that are consistent with this specification should be adopted.

1. A method of forming a thin film device comprising:
depositing a layer of material on a substrate with a thin film system at a deposition rate;
monitoring a density of the layer of material in-situ with X-ray reflectivity to control the deposition rate;
selecting a threshold for the deposition rate for a consistent film density, wherein the threshold is a material density;
decreasing the deposition rate when the deposition rate is higher than the threshold; and
increasing the deposition rate when the deposition rate is lower than the threshold.

2. The method of claim 1, wherein monitoring the density is performed in-situ.

3. (canceled)

4. (canceled)

5. The method of claim 1, wherein the threshold is an optical thickness of the layer of material.

6. The method of claim 1, wherein the threshold is an optical property of the material.

7. The method of claim 1, further comprising adjusting the thin film system by changing an E-beam current.

8. The method of claim 1, further comprising adjusting the thin film system by changing an ion-source current.

9. The method of claim 1, further comprising adjusting the thin film system by changing an ion-source voltage.

10. The method of claim 1, wherein monitoring a density of the layer of material is performed by an ellipsometer, a spectrometer, or an interferometer.

11. A thin film system for fabricating a thin film device, comprising:
a chamber;
a material source contained with the chamber;
an electrical component to activate the material source;
a substrate holder to support a multilayer stack of materials that form the thin film device;
a measurement device; and
an information handling system configured to control the measurement device to monitor a density of a layer of material deposited on a substrate in-situ with X-ray reflectivity to control a deposition rate, select a threshold for the deposition rate for a consistent film density;
decrease the deposition rate when the deposition rate is higher than the threshold with the electrical component or increase the deposition rate when the deposition rate is lower than the threshold with the electrical component.

12. The thin film system of claim 11, wherein the measurement device comprises an ellipsometer, a spectrometer, or an interferometer.

13. The thin film system of claim 11, wherein the information handling system operates in-situ to decrease the deposition rate or increase the deposition rate.

14. (canceled)

15. The thin film system of claim 11, wherein the threshold is an optical thickness of the layer of material.

16. The thin film system of claim 11, wherein the threshold is an optical property of the material.

17. The thin film system of claim 11, wherein the information handling system is further configured to adjust the thin film system by changing an E-beam current.

18. The thin film system of claim 11, wherein the information handling system is further configured to adjust the thin film system by changing an ion-source current.

19. The thin film system of claim 11, wherein the information handling system is further configured to adjust the thin film system by changing an ion-source voltage.

20. The thin film system of claim 11, wherein the threshold is a stoichiometry of the layer of material.
